(19) United States
(12) Patent Application Publication
(10) Pub. No.: US 2025/0216669 A1
(43) Pub. Date: Jul. 3, 2025

(54) MICROMIRROR DEVICE AND OPTICAL SCANNING DEVICE

(71) Applicant: FUJIFILM Corporation, Tokyo (JP)

(72) Inventor: Keisuke AOSHIMA, Kanagawa (JP)

(73) Assignee: FUJIFILM Corporation, Tokyo (JP)

(21) Appl. No.: 19/082,318

(22) Filed: Mar. 18, 2025

Related U.S. Application Data
(63) Continuation of application No. PCT/JP2023/031287, filed on Aug. 29, 2023.

(30) Foreign Application Priority Data
Sep. 20, 2022 (JP) 2022-149486

(51) Int. Cl. G02B 26/08; G02B 26/10

(52) U.S. Cl. CPC G02B 26/0833; G02B 26/101

(57) ABSTRACT

The micromirror device includes a mirror portion, a support portion, a movable frame, a second support portion, a driving part, a fixed frame, and a connecting portion. The first support portion is line-symmetrical about the first axis. The second support portion is line-symmetrical about the second axis and includes a second swing shaft disposed on the second axis and a second coupling part. One end of the second swing shaft is connected to the movable frame and the other end is connected to the second coupling part, and the second coupling part extends in a direction from an outer end portion of the second swing shaft on the second axis toward the mirror portion and is connected to the driving part in a region adjacent to the movable frame. The connecting portion is line-symmetrical about the second axis and supports the driving part to be swingable around it.

### CROSS-REFERENCE TO RELATED APPLICATIONS

This application is a continuation application of International Application No. PCT/JP2023/031287, filed Aug. 29, 2023, the disclosure of which is incorporated herein by reference in its entirety. Further, this application claims priority from Japanese Patent Application No. 2022-149486, filed on Sep. 20, 2022, the disclosure of which is incorporated herein by reference in its entirety.

### BACKGROUND

### 1. Technical Field

The technique of the present disclosure relates to a micromirror device and an optical scanning device.

### 2. Description of the Related Art

A micromirror device (also referred to as a microscanner) is known as one of micro electro mechanical systems (MEMS) devices manufactured using the silicon (Si) nanofabrication technique. Since the micromirror device is small and has low power consumption, it is expected to have a wide range of applications in laser displays, laser projectors, optical coherence tomography, and the like.

There are various methods for driving the micromirror device, and a piezoelectric drive type using deformation of a piezoelectric material is promising since the generated torque is higher than that in other methods and a high scan angle can be obtained. In particular, in a case where a high scan angle is required, such as in a laser display, a higher scan angle can be obtained by resonantly driving the micromirror device of the piezoelectric drive type.

A general micromirror device used in a laser display comprises a mirror portion and a piezoelectric actuator (see, for example, JP2017-132281A). The mirror portion is swingable around a first axis and a second axis that are orthogonal to each other. The actuator is a driving part that causes the mirror portion to swing around a first axis and a second axis in accordance with a driving voltage supplied from the outside.

### SUMMARY

As performance indicators of the laser display, resolution and viewing angle are mentioned. The resolution and the viewing angle are greatly affected by the swing frequency and the deflection angle of the mirror portion. For example, in a Lissajous scan type laser display, a mirror portion performs two-dimensional optical scanning by simultaneously swinging around a first axis and a second axis at different frequencies. In this case, as the deflection angle of the mirror portion increases, the scanning area of light increases, and a larger image can be displayed with a shorter optical path length.

In order to increase the deflection angle of the mirror portion, the simplest method is to increase the area of the driving part to increase the driving torque. However, increasing the area of the driving part leads to an increase in the size of the micromirror device, which is contrary to the miniaturization required for the micromirror device for a laser display application.

In order to solve this problem, in the micromirror device using the resonance driving, the deflection angle of the mirror portion is often improved by adjusting the resonance mode. For example, in the resonance mode in which the mirror portion and the driving part swing in anti-phases, the gain of the deflection angle with respect to the applied voltage to the driving part is large. However, in the anti-phase resonance mode, a large stress is applied to the swing shaft, and thus it is not easy to increase the deflection angle from the viewpoint of durability.

An object of the technology of the present disclosure is to provide a micromirror device and an optical scanning device that can realize a large deflection angle without increasing an area of a driving part.

In order to achieve the above object, a micromirror device of the present disclosure comprises: a mirror portion that has a reflecting surface for reflecting incident light; a pair of first support portions that are connected to the mirror portion on a first axis located in a plane including the reflecting surface in a stationary state of the mirror portion and that support the mirror portion to be swingable around the first axis; a pair of movable frames that are connected to the first support portions and that face each other across the first axis; a pair of second support portions that are connected to the movable frames on a second axis provided in the plane and perpendicular to the first axis and that support the mirror portion, the first support portions, and the movable frames to be swingable around the second axis; a driving part that is connected to the second support portions and that is disposed to surround the movable frames; a fixed frame that is disposed to surround the driving part; and a pair of connecting portions that connect the driving part and the fixed frame, in which the first support portion has a shape that is line-symmetrical about the first axis, the second support portion has a shape that is line-symmetrical about the second axis and includes a second swing shaft disposed on the second axis and a pair of second coupling parts disposed at positions facing each other across the second axis, one end of the second swing shaft is connected to the movable frame and the other end of the second swing shaft is connected to the second coupling part, the second coupling part extends in a direction from an outer end portion of the second swing shaft on the second axis toward the mirror portion and is connected to the driving part in a region adjacent to the movable frame, and the connecting portion has a shape that is line-symmetrical about the second axis and supports the driving part to be swingable around the second axis.

It is preferable that the driving part includes a pair of first actuators that are connected to the second support portion, that face each other across the second axis, and that each include a piezoelectric element, and a pair of second actuators that are disposed to surround the first actuators, that face each other across the first shaft, and that each include a piezoelectric element.

It is preferable that the connecting portions are disposed on the second axis.

It is preferable that the first support portion includes a first swing shaft having a shape that is line-symmetrical about the first axis, and disposed on the first axis, and a pair of first coupling parts disposed at positions facing each other across the first axis.

It is preferable that one end of the first swing shaft is connected to the mirror portion and the other end of the first swing shaft is connected to the first coupling part, and the first coupling part extends in a direction from an outer end portion of the first swing shaft on the first axis toward the mirror portion, is bent in an outer circumferential direction in a region adjacent to the mirror portion, and is bent again in a region adjacent to the driving part to be connected to the movable frame.

It is preferable that one end of the first swing shaft is connected to the mirror portion and the other end of the first swing shaft is connected to the first coupling part, and the first coupling part extends in a direction from an outer end portion of the first swing shaft on the first axis toward the mirror portion and is connected to the movable frame in a region adjacent to the mirror portion.

It is preferable that the first coupling part protrudes from a portion connected to the movable frame to an outer end portion of the first swing shaft on the first axis in a direction of the first axis.

It is preferable that the first coupling part is bent in an outward direction from an outer end portion of the first swing shaft on the first axis, forms an annular region in a region adjacent to the movable frame, further extends from the annular region along the first axis, and extends along the driving part in a region adjacent to the driving part to be connected to the movable frame.

It is preferable that the pair of first coupling parts are connected in a region adjacent to the driving part.

According to the present disclosure, there is provided an optical scanning device comprising: the micromirror device described above; and a processor that drives the driving part, in which the processor applies a drive signal to the driving part to cause the mirror portion to swing around each of the first axis and the second axis.

According to the technology of the present disclosure, it is possible to provide a micromirror device and an optical scanning device that can realize a large deflection angle without increasing the area of the driving part.

### BRIEF DESCRIPTION OF THE DRAWINGS

Exemplary embodiments according to the technique of the present disclosure will be described in detail based on the following figures, wherein:

FIG. 1 is a schematic view of an optical scanning device,

FIG. 2 is a block diagram showing an example of a hardware configuration of a driving controller,

FIG. 3 is an external perspective view of a micromirror device according to the first embodiment,

FIG. 4 is a plan view of the micromirror device according to the first embodiment as viewed from a light incident side,

FIG. 5 is a cross-sectional view taken along the line A-A of FIG. 4,

FIG. 6 is a cross-sectional view showing a state where a mirror portion rotates around a first axis,

FIGS. 7A and 7B are diagrams showing examples of a first drive signal and a second drive signal,

FIG. 8 is a diagram showing parameters relating to dimensions of components of the micromirror device,

FIG. 9 is a diagram showing parameters relating to dimensions of components of the micromirror device,

FIG. 10 is a diagram showing specific set values of the parameters,

FIG. 11 is a plan view of a micromirror device according to a second embodiment as viewed from a light incident side,

FIG. 12 is a diagram showing parameters relating to dimensions of components of the micromirror device,

FIG. 13 is a diagram showing parameters relating to dimensions of components of the micromirror device,

FIG. 14 is a diagram showing specific set values of the parameters,

FIG. 15 is a plan view of a micromirror device according to a third embodiment as viewed from a light incident side,

FIG. 16 is a diagram showing parameters relating to dimensions of components of the micromirror device,

FIG. 17 is a diagram showing parameters relating to dimensions of components of the micromirror device,

FIG. 18 is a diagram showing specific set values of the parameters,

FIG. 19 is a plan view of the micromirror device according to the fourth embodiment as viewed from a light incident side,

FIG. 20 is a diagram showing parameters relating to dimensions of components of the micromirror device,

FIG. 21 is a diagram showing parameters relating to dimensions of components of the micromirror device,

FIG. 22 is a diagram showing specific set values of the parameters,

FIG. 23 is a plan view of a micromirror device according to a fifth embodiment as viewed from a light incident side,

FIG. 24 is a diagram showing parameters relating to dimensions of components of the micromirror device,

FIG. 25 is a diagram showing parameters relating to dimensions of components of the micromirror device,

FIG. 26 is a diagram showing specific set values of the parameters,

FIG. 27 is a plan view of a micromirror device according to a first comparative example as viewed from a light incident side,

FIG. 28 is a diagram showing parameters relating to dimensions of components of the micromirror device,

FIG. 29 is a diagram showing specific set values of the parameters,

FIG. 30 is a plan view of a micromirror device according to a second comparative example as viewed from a light incident side,

FIG. 31 is a diagram showing parameters relating to dimensions of components of the micromirror device,

FIG. 32 is a diagram showing parameters relating to dimensions of components of the micromirror device,

FIG. 33 is a diagram showing parameters relating to dimensions of components of the micromirror device,

FIG. 34 is a diagram showing specific set values of the parameters, and

FIG. 35 is a diagram showing results of experiments and simulations according to each of the embodiments and each of the comparative examples.

### DETAILED DESCRIPTION

An example of an embodiment according to the technology of the present disclosure will be described with reference to the accompanying drawings.

### First Embodiment

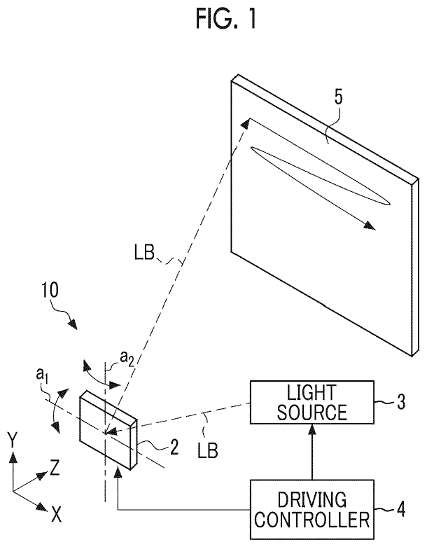

FIG. 1 is a schematic view of an optical scanning device 10 according to the first embodiment. The optical scanning device 10 includes a micromirror device (hereinafter, referred to as MMD) 2, a light source 3, and a driving controller 4. The optical scanning device 10 optically scans a surface to be scanned 5 by reflecting a light beam LB emitted from the light source 3 by the MMD 2 under the control of the driving controller 4. The surface to be scanned 5 is, for example, a screen.

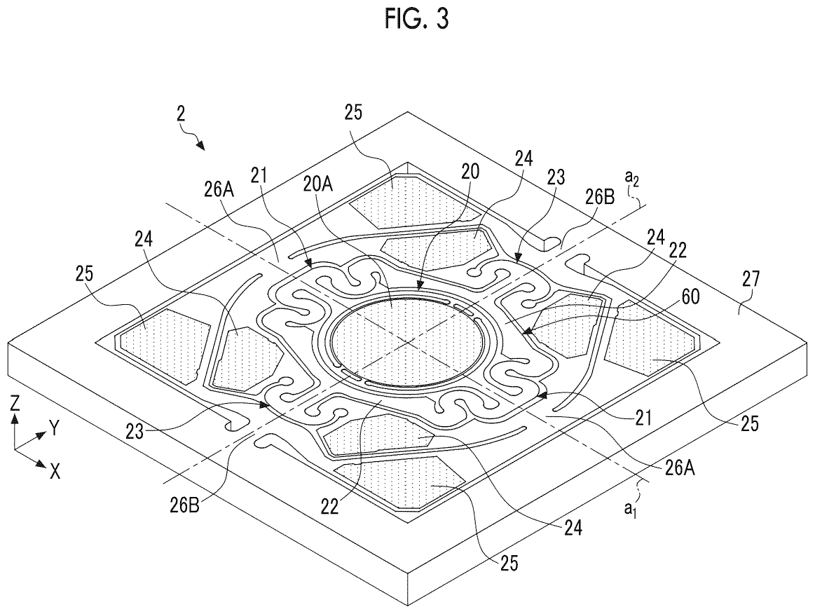

The MMD 2 is a piezoelectric biaxial drive-type micromirror device capable of allowing a mirror portion 20 (see FIG. 3) to swing around a first axis a₁ and a second axis a₂ perpendicular to the first axis a₁. Hereinafter, a direction parallel to the first axis a₁ is referred to as an X direction, a direction parallel to the second axis a₂ is a Y direction, and a direction perpendicular to the first axis a₁ and the second axis a₂ is referred to as a Z direction.

The light source 3 is a laser device that emits, for example, laser light as the light beam LB. It is preferable that the light source 3 emits the light beam LB perpendicularly to a reflecting surface 20A (see FIG. 3) included in the mirror portion 20 in a state where the mirror portion 20 of the MMD 2 is stationary.

The driving controller 4 outputs a drive signal to the light source 3 and the MMD 2 based on optical scanning information. The light source 3 generates the light beam LB based on the input drive signal and emits the light beam LB to the MMD 2. The MMD 2 allows the mirror portion 20 to swing around the first axis a₁ and the second axis a₂ based on the input drive signal.

As will be described in detail below, the driving controller 4 allows the mirror portion 20 to resonate around the first axis a₁ and the second axis a₂, so that the surface to be scanned 5 is scanned with the light beam LB reflected by the mirror portion 20 such that a Lissajous waveform is drawn. This optical scanning type is called a Lissajous scanning type.

The optical scanning device 10 is applied to, for example, a Lissajous scanning type laser display. Specifically, the optical scanning device 10 can be applied to a laser scanning display such as augmented reality (AR) glass or virtual reality (VR) glass.

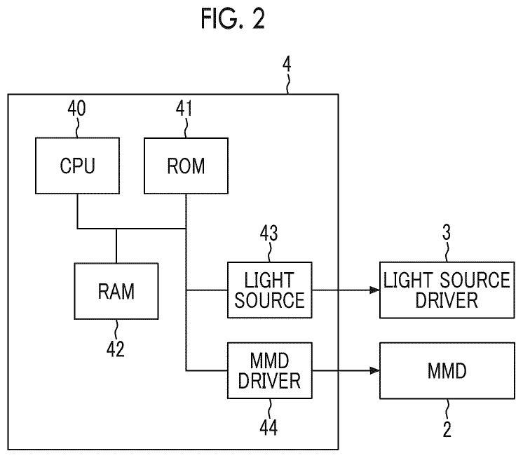

FIG. 2 shows an example of a hardware configuration of the driving controller 4. The driving controller 4 has a central processing unit (CPU) 40, a read only memory (ROM) 41, a random access memory (RAM) 42, a light source driver 43, and an MMD driver 44. The CPU 40 is an arithmetic unit that realizes the entire function of the driving controller 4 by reading out a program and data from a storage device such as the ROM 41 into the RAM 42 and executing processing. The CPU 40 is an example of a “processor” according to the technology of the present disclosure.

The ROM 41 is a non-volatile storage device and stores a program for the CPU 40 to execute processing and data such as the optical scanning information described above. The RAM 42 is a volatile storage device that temporarily holds a program and data.

The light source driver 43 is an electric circuit that outputs a drive signal to the light source 3 under the control of the CPU 40. In the light source driver 43, the drive signal is a driving voltage for controlling the irradiation timing and the irradiation intensity of the light source 3.

The MMD driver 44 is an electric circuit that outputs a drive signal to the MMD 2 under the control of the CPU 40. In the MMD driver 44, the drive signal is a driving voltage for controlling the timing, cycle, and deflection angle for allowing the mirror portion 20 of the MMD 2 to swing.

The CPU 40 controls the light source driver 43 and the MMD driver 44 based on the optical scanning information. The optical scanning information is information including the scanning pattern of the light beam LB with which the surface to be scanned 5 is scanned and the light emission timing of the light source 3.

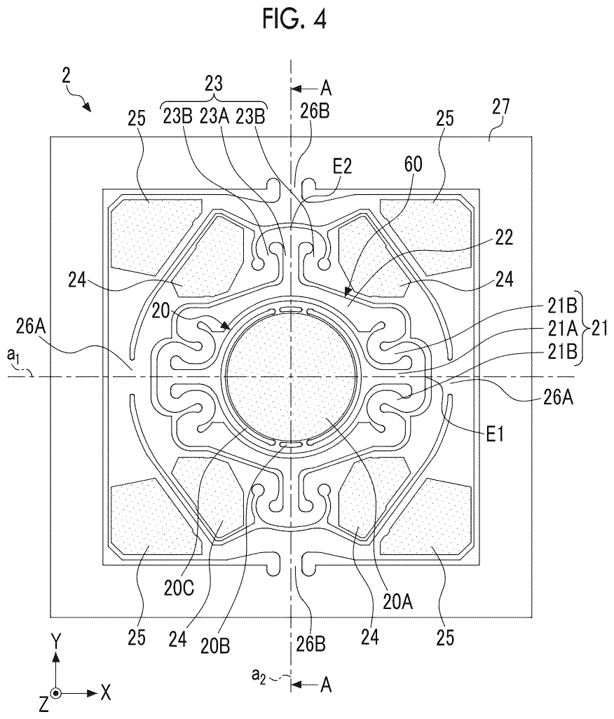

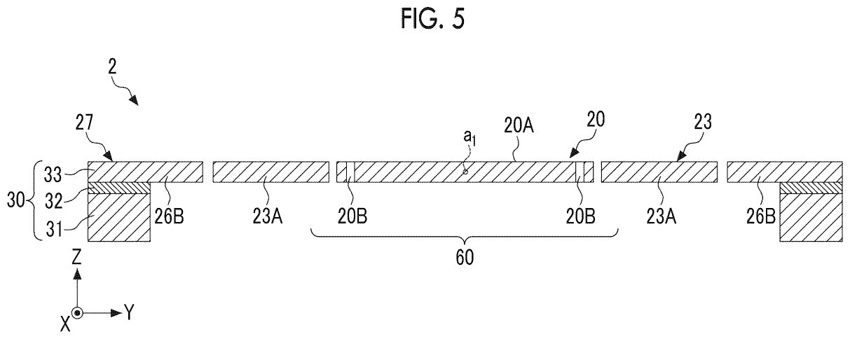

Next, the configuration of the MMD 2 according to a first embodiment will be described with reference to FIGS. 3 to 5. FIG. 3 is an external perspective view of the MMD 2. FIG. 4 is a plan view of the MMD 2 as viewed from the light incident side. FIG. 5 is a cross-sectional view taken along the line A-A in FIG. 4.

As shown in FIG. 3, the MMD 2 has the mirror portion 20, a pair of first support portions 21, a pair of movable frames 22, a pair of second support portions 23, a pair of first actuators 24, a pair of second actuators 25, a pair of first connecting portions 26A, a pair of second connecting portions 26B, and a fixed frame 27. The MMD 2 is a so-called MEMS scanner.

The mirror portion 20 has a reflecting surface 20A for reflecting incident light. The reflecting surface 20A is provided on one surface of the mirror portion 20, and is formed of a metal thin film such as gold (Au) and aluminum (Al). The shape of the reflecting surface 20A is, for example, circular with the intersection of the first axis a₁ and the second axis a₂ as the center.

The first axis a₁ and the second axis a₂ exist, for example, in a plane including the reflecting surface 20A in a case where the mirror portion 20 is stationary. The planar shape of the MMD 2 is rectangular, line-symmetrical about the first axis a₁, and line-symmetrical about the second axis a₂.

The pair of first support portions 21 are disposed at positions facing each other across the second axis a₂, and have a shape that is line-symmetrical about the second axis a₂. In addition, each of the first support portions 21 has a shape that is line-symmetrical about the first axis a₁. The first support portions 21 are connected to the mirror portion 20 on the first axis a₁, and swingably support the mirror portion 20 around the first axis a₁.

The pair of movable frames 22 are disposed at positions facing each other across the first axis a₁, and have a shape that is line-symmetrical about the first axis a₁. Each of the movable frames 22 has a shape that is line-symmetrical about the second axis a₂. In addition, each of the movable frames 22 is curved along the outer periphery of the mirror portion 20. Both ends of the movable frame 22 are connected to the first support portion 21.

The first support portion 21 and the movable frame 22 are connected to each other to surround the mirror portion 20. The mirror portion 20, the first support portion 21, and the movable frame 22 constitute a movable portion 60.

The pair of second support portions 23 are disposed at positions facing each other across the first axis a₁, and have a shape that is line-symmetrical about the first axis a₁. Each of the second support portions 23 has a shape that is line-symmetrical about the second axis a₂. The second support portion 23 is connected to the movable frame 22 on the second axis a₂, and swingably supports the movable portion 60 having the mirror portion 20 around the second axis a₂. In addition, both ends of the second support portion 23 are connected to the first actuator 24.

The pair of first actuators 24 are disposed at positions facing each other across the second axis a₂, and have a shape that is line-symmetrical about the second axis a₂. In addition, the first actuators 24 have a shape that is line-symmetrical about the first axis a₁. The first actuator 24 is formed along the outer periphery of the movable frame 22 and the first support portion 21. The first actuator 24 is a piezoelectric drive type actuator comprising a piezoelectric element.

The first actuator 24 is electrically connected across the first axis a₁ by a wiring line (not shown). The pair of first actuators 24 disposed across the second axis a₂ are electrically separated.

The second support portion 23 and the first actuator 24 are connected to each other to surround the movable portion 60.

The pair of second actuators 25 are disposed at positions facing each other across the first axis a₁, and have a shape that is line-symmetrical about the first axis a₁. In addition, the second actuators 25 have a shape that is line-symmetrical about the second axis a₂. The second actuator 25 is formed along the outer periphery of the first actuator 24 and the second support portion 23. The second actuator 25 is a piezoelectric drive type actuator comprising a piezoelectric element.

The second actuators 25 are electrically connected to each other across the second axis a₂ by a wiring line (not shown). The pair of second actuators 25 disposed across the first axis a₁ are electrically separated.

The pair of first connecting portions 26A are disposed at positions facing each other across the second axis a₂, and have a shape that is line-symmetrical about the second axis a₂. In addition, each of the first connecting portions 26A has a shape that is line-symmetrical about the first axis a₁. The first connecting portion 26A is disposed along the first axis a₁, and connects the first actuator 24 and the second actuator 25 on the first axis a₁.

The pair of second connecting portions 26B are disposed at positions facing each other across the first axis a₁, and have a shape that is line-symmetrical about the first axis a₁. In addition, each of the second connecting portions 26B is stretched in the Y direction, and has a shape that is line-symmetrical about the second axis a₂. The second connecting portion 26B is disposed along the second axis a₂, and connects the second actuator 25 and the fixed frame 27 on the second axis a₂. The second connecting portion 26B supports the second actuator 25 to be swingable around the second axis a₂. The second connecting portion 26B corresponds to a “connecting portion” according to the technology of the present disclosure.

The second actuator 25 surrounds the first actuator 24. The first actuator 24 and the second actuator 25 constitute a driving part disposed around the movable frame 22.

The fixed frame 27 is a frame-shaped member having a rectangular outer shape, and has a shape that is line-symmetrical about each of the first axis a₁ and the second axis a₂. The fixed frame 27 surrounds the outer periphery of the second actuator 25 and the second connecting portion 26B. That is, the fixed frame 27 is disposed around the driving part.

The first actuator 24 and the second actuator 25 are piezoelectric actuators each including a piezoelectric element. The pair of first actuators 24 allow the movable portion 60 to swing around the second axis a₂ by applying rotational torque around the second axis a₂ to the mirror portion 20 and the movable frame 22. The pair of second actuators 25 allow the mirror portion 20 to swing around the first axis a₁ by applying rotational torque around the first axis a₁ to the mirror portion 20, the movable frame 22, and the first actuator 24.

As shown in FIG. 4, the first support portion 21 is composed of a swing shaft 21A and a pair of coupling parts 21B. The swing shaft 21A is a so-called torsion bar extended along the first axis a₁. One end of the swing shaft 21A is connected to the mirror portion 20, and the other end thereof is connected to the coupling part 21B.

The pair of coupling parts 21B are disposed at positions facing each other across the first axis a₁, and have a shape that is line-symmetrical about the first axis a₁. One end of the coupling part 21B is connected to the outer end portion E1 on the first axis a₁ of the swing shaft 21A, and the other end thereof is connected to the movable frame 22. The coupling part 21B has a folded structure. Specifically, the coupling part 21B extends in a direction from the outer end portion E1 of the swing shaft 21A on the first axis a₁ toward the mirror portion 20, is bent in the outer circumferential direction in a region adjacent to the mirror portion 20, and is bent again in a region adjacent to the first actuator 24 to be connected to the movable frame 22. As described above, since the coupling part 21B has elasticity due to the folded structure, the internal stress applied to the swing shaft 21A is relaxed in a case where the mirror portion 20 swings around the first axis a₁. The swing shaft 21A and the coupling part 21B correspond to a “first swing shaft” and a “first coupling part” according to the technology of the present disclosure, respectively.

The second support portion 23 is composed of a swing shaft 23A and a pair of coupling parts 23B. The swing shaft 23A is a so-called torsion bar extended along the second axis a₂. One end of the swing shaft 23A is connected to the movable frame 22, and the other end thereof is connected to the coupling part 23B.

The pair of coupling parts 23B are disposed at positions facing each other across the second axis a₂, and have a shape that is line-symmetrical about the second axis a₂. One end of the coupling part 23B is connected to the outer end portion E2 on the second axis a₂ of the swing shaft 23A, and the other end thereof is connected to the first actuator 24. The coupling part 23B has a folded structure. Specifically, the coupling part 23B extends from the outer end portion E2 on the second axis a₂ of the swing shaft 23A in a direction toward the mirror portion 20 and is connected to the first actuator 24 in a region adjacent to the movable frame 22. As described above, since the coupling part 23B has elasticity due to the folded structure, the internal stress applied to the swing shaft 23A is relaxed in a case where the mirror portion 20 swings around the second axis a₂. The swing shaft 23A and the coupling part 23B correspond to a “second swing shaft” and a “second coupling part” according to the technology of the present disclosure, respectively.

In the mirror portion 20, a plurality of slits 20B and 20C are formed on the outside of the reflecting surface 20A along the outer periphery of the reflecting surface 20A. The plurality of slits 20B and 20C are disposed at positions that are line-symmetrical about the first axis a₁ and the second axis a₂, respectively. The slit 20B has an effect of suppressing distortion generated on the reflecting surface 20A due to the swing of the mirror portion 20.

In FIGS. 3 and 4, the wiring line and the electrode pad for giving the drive signal to the first actuator 24 and the second actuator 25 are not shown. A plurality of the electrode pads are provided on the fixed frame 27.

As shown in FIG. 5, the MMD 2 is formed, for example, by performing an etching treatment on a silicon on insulator (SOI) substrate 30. The SOI substrate 30 is a substrate in which a silicon oxide layer 32 is provided on a first silicon active layer 31 made of single crystal silicon, and a second silicon active layer 33 made of single crystal silicon is provided on the silicon oxide layer 32.

The mirror portion 20, the first support portion 21, the movable frame 22, the second support portion 23, the first actuator 24, the second actuator 25, the first connecting portion 26A, and the second connecting portion 26B are formed of the second silicon active layer 33 remaining by removing the first silicon active layer 31 and the silicon oxide layer 32 from the SOI substrate 30 by an etching treatment. The second silicon active layer 33 functions as an clastic portion having elasticity. The fixed frame 27 is formed of three layers of the first silicon active layer 31, the silicon oxide layer 32, and the second silicon active layer 33. That is, the mirror portion 20, the first support portion 21, the movable frame 22, the second support portion 23, the first actuator 24, the second actuator 25, the first connecting portion 26A, and the second connecting portion 26B have a thinner thickness than the fixed frame 27. In the present disclosure, the thickness means a width in the Z direction.

The first actuator 24 includes a piezoelectric element (not shown) formed on the second silicon active layer 33. The piezoelectric element has a laminated structure in which a lower electrode, a piezoelectric film, and an upper electrode are sequentially laminated on the second silicon active layer 33. The second actuator 25 has the same configuration as the first actuator 24.

The lower electrode and the upper electrode are formed of, for example, metal such as gold (Au) or platinum (Pt). The piezoelectric film is formed of, for example, lead zirconate titanate (PZT), which is a piezoelectric material. The lower electrode and the upper electrode are electrically connected to the driving controller 4 described above via the wiring line and the electrode pad.

The lower electrode is connected to the driving controller 4 via the wiring line and the electrode pad, and a ground potential is applied thereto. A driving voltage is applied to the upper electrode from the driving controller 4.

In a case where a positive or negative voltage is applied to the piezoelectric film in the polarization direction, deformation (for example, expansion and contraction) proportional to the applied voltage occurs. That is, the piezoelectric film exerts a so-called inverse piezoelectric effect. The piezoelectric film exerts an inverse piezoelectric effect by applying a driving voltage from the driving controller 4 to the upper electrode, and displaces the first actuator 24 and the second actuator 25.

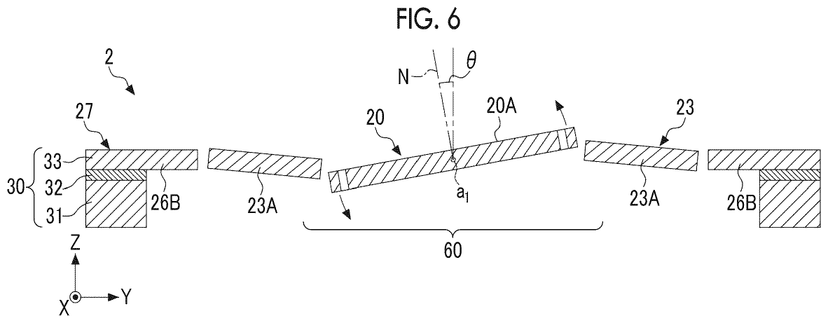

FIG. 6 shows an example in which one piezoelectric film of the pair of second actuators 25 is extended and the other piezoelectric film is contracted, thereby generating rotational torque around the first axis a₁ in the second actuator 25. In this way, one of the pair of second actuators 25 and the other are displaced in opposite directions to each other, whereby the mirror portion 20 rotates around the first axis a₁.

In addition, FIG. 6 shows an example in which the second actuator 25 is driven in an anti-phase resonance mode (hereinafter, referred to as an anti-phase rotation mode) in which the displacement direction of the pair of second actuators 25 and the rotation direction of the mirror portion 20 are opposite to each other. On the other hand, an in-phase resonance mode in which the displacement direction of the pair of second actuators 25 and the rotation direction of the mirror portion 20 are the same direction is called an in-phase rotation mode. In the present embodiment, the second actuator 25 is driven in the anti-phase rotation mode.

A deflection angle θ of the mirror portion 20 around the first axis a₁ is controlled by the drive signal (hereinafter, referred to as a first drive signal) given to the second actuator 25 by the driving controller 4. The first drive signal is, for example, a sinusoidal AC voltage. The first drive signal includes a driving voltage waveform V_{1A} (t) applied to one of the pair of second actuators 25 and a driving voltage waveform V_{1B} (t) applied to the other. The driving voltage waveform V_{1A} (t) and the driving voltage waveform V_{1B} (t) are in an anti-phase with each other (that is, the phase difference is 180°).

The deflection angle θ of the mirror portion 20 around the first axis a₁ corresponds to an angle at which the normal line N of the reflecting surface 20A is inclined with respect to the Z direction in the YZ plane.

The first actuator 24 is driven in the anti-phase rotation mode similarly to the second actuator 25. A deflection angle of the mirror portion 20 around the second axis a₂ is controlled by the drive signal (hereinafter, referred to as a second drive signal) given to the first actuator 24 by the driving controller 4. The second drive signal is, for example, a sinusoidal AC voltage. The second drive signal includes a driving voltage waveform V_{2A} (t) applied to one of the pair of first actuators 24 and a driving voltage waveform V_{2B} (t) applied to the other. The driving voltage waveform V_{2A} (t) and the driving voltage waveform V_{2B} (t) are in an anti-phase with each other (that is, the phase difference is 180°).

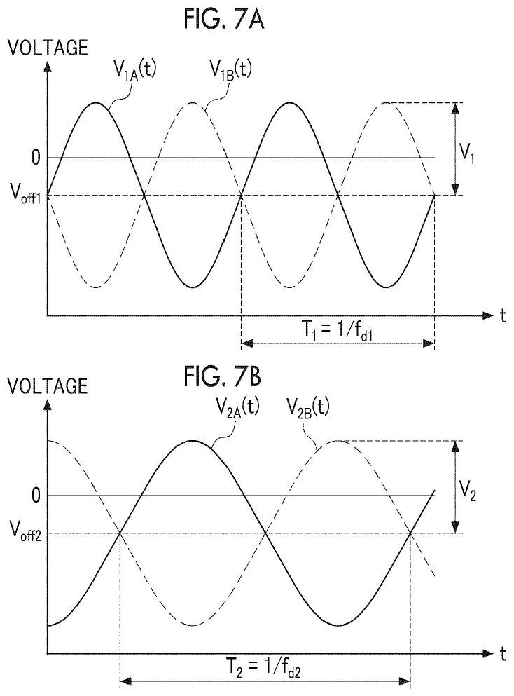

FIGS. 7A and 7B show examples of the first drive signal and the second drive signal. FIG. 7A shows the driving voltage waveforms V_{1A} (t) and V_{1B} (t) included in the first drive signal. FIG. 7B shows the driving voltage waveforms V_{2A} (t) and V_{2B} (t) included in the second drive signal.

The driving voltage waveforms V_{1A} (t) and V_{1B} (t) are represented as follows, respectively.

$${V}_{1 A} ( t ) = {V}_{off 1} + {V}_{1} sin ( 2 π {f}_{d 1} t )$$

$${V}_{1 B} ( t ) = {V}_{off 1} + {V}_{1} sin ( 2 π {f}_{d 1} t + α )$$

Here, V₁ is the amplitude voltage. V_{off1} is the bias voltage. f_{d1} is the driving frequency (hereinafter, referred to as the first driving frequency). t is time. α is the phase difference between the driving voltage waveforms V_{1A} (t) and V_{1B} (t). In the present embodiment, for example, α=180°.

By applying the driving voltage waveforms V_{1A} (t) and V_{1B} (t) to the pair of second actuators 25, the mirror portion 20 swings around the first axis a₁ at the first driving frequency f_{d1}.

The driving voltage waveforms V_{2A} (t) and V_{2B} (t) are represented as follows, respectively.

$${V}_{2 A} ( t ) = {V}_{off 2} + {V}_{2} sin ( 2 π {f}_{d 2} t + φ )$$

$${V}_{2 B} ( t ) = {V}_{off 2} + {V}_{2} sin ( 2 π {f}_{d 2} t + β + φ )$$

Here, V₂ is the amplitude voltage. V_{off2} is the bias voltage. f_{d2} is the driving frequency (hereinafter, referred to as the second driving frequency). t is time. β is the phase difference between the driving voltage waveforms V_{2A} (t) and V_{2B} (t). In the present embodiment, for example, β=180°. In addition, φ is the phase difference between the driving voltage waveforms V_{1A} (t) and V_{1B} (t) and the driving voltage waveforms V_{2A} (t) and V_{2B} (t). In the present embodiment, for example, V_{off1}=V_{off2}=0 V.

By applying the driving voltage waveforms V_{2A} (t) and V_{2B} (t) to the pair of first actuators 24, the movable portion 60 including the mirror portion 20 swings around the second axis a₂ at the second driving frequency f_{d2}.

The first driving frequency f_{d1} is set so as to match the resonance frequency around the first axis a₁ of the mirror portion 20. The second driving frequency f_{d2} is set so as to match the resonance frequency around the second axis a₂ of the mirror portion 20. For example, the first driving frequency f_{d1} is larger than the second driving frequency f_{d2}.

The applicant has found that, by configuring the MMD 2 as described above, a large deflection angle can be realized in the anti-phase rotation mode without increasing the area of the driving part. In addition, in the MMD 2, since the first support portion 21 and the second support portion 23 are separated from the driving part at the outer end portions E1 and E2, respectively, the concentration of stress at one location during driving is suppressed. As a result, the first support portion 21 and the second support portion 23 are suppressed from causing Si structure destruction, and a large deflection angle can be realized.

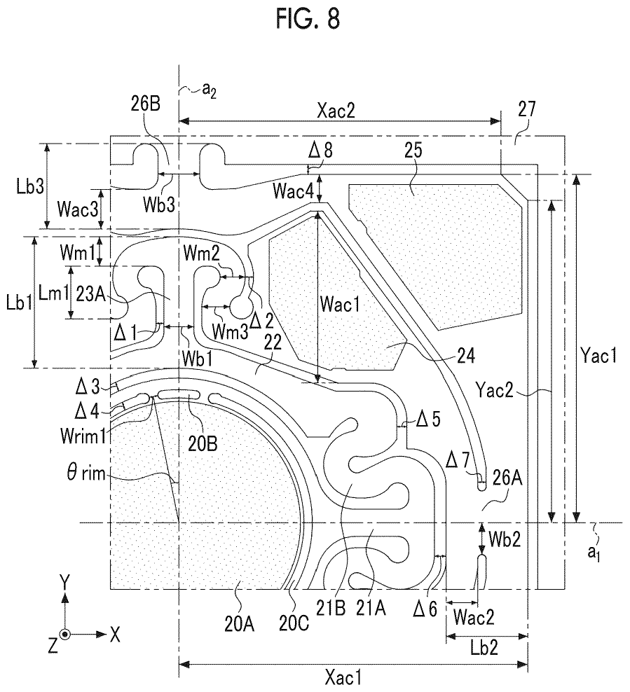

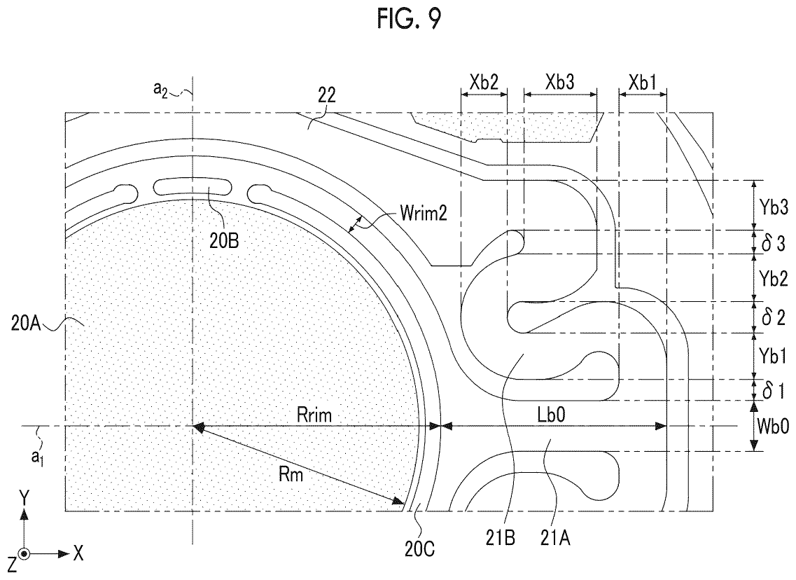

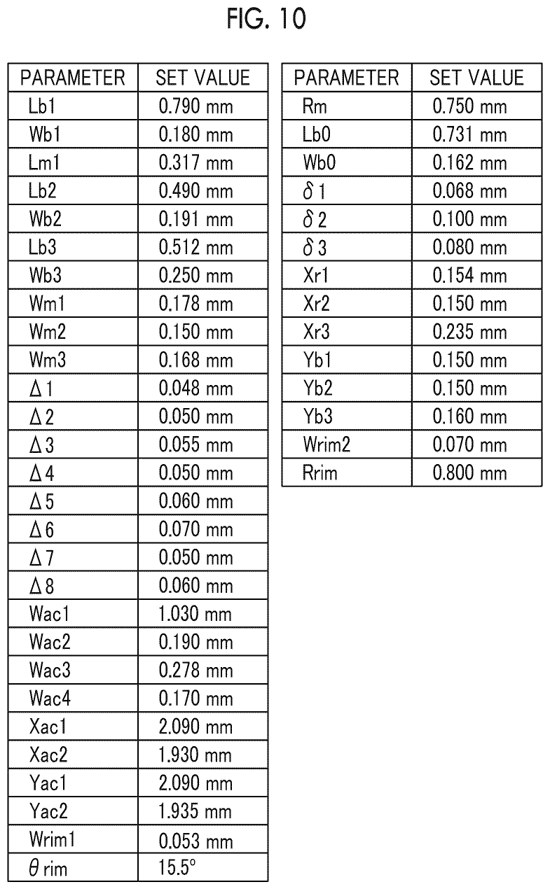

In order to verify the above-described effect, the present applicant produced a sample of MMD2 and performed an experiment. FIGS. 8 and 9 show parameters relating to the width, length, and the like of the components of the sample used in the experiment. FIG. 10 is a diagram showing specific set values of the parameters.

In addition, the diameter of the mirror portion 20 was set to 1.5 mm, the thickness of the SOI substrate 30 was set to 430 μm, and the thickness of the second silicon active layer 33 was set to 100 μm. The length of one side of the fixed frame 27 was 5.5 mm.

In the present experiment, the mirror portion 20 was resonantly driven in the anti-phase rotation mode around the second axis a₂ in a vacuum (less than 50 Pa), and the driving voltage (that is, the amplitude voltage V₂) required for θ=11.25° was confirmed. θ=11.25° corresponds to 45° in terms of the scanning angle (full angle) of the light beam LB. As a result of the experiment, the required driving voltage at θ=11.25° was 3.8 V.

In addition, a resonance mode analysis simulation was performed by the finite element method. Specifically, the mirror portion 20 was resonantly driven in the anti-phase rotation mode around the second axis a₂, and the Mises stress applied to the second support portion 23 at θ=11.25° was calculated. The calculated value of the Mises stress was 1.79 GPa.

### Second Embodiment

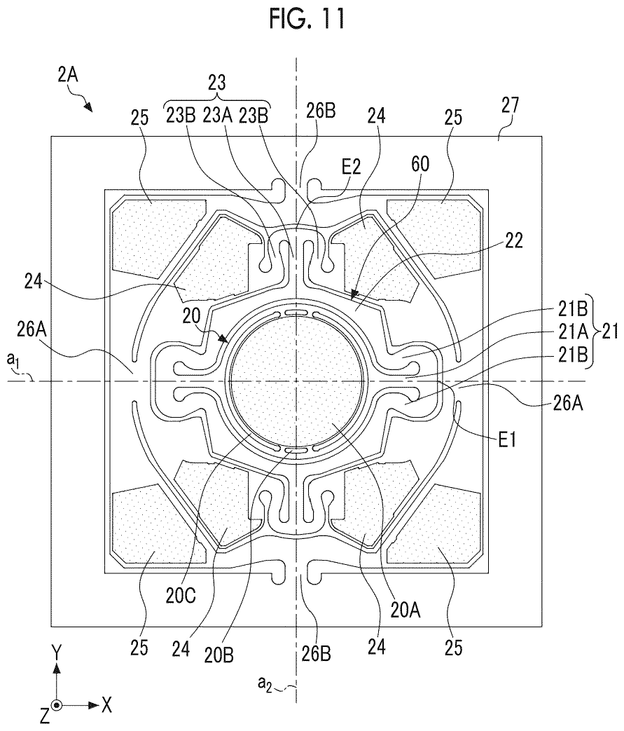

Next, a second embodiment will be described. FIG. 11 is a plan view of the MMD 2A according to the second embodiment as viewed from the light incident side. The MMD 2A is different from the MMD 2 according to the first embodiment only in the configuration of the first support portion 21.

In the present embodiment, the first support portion 21 is configured with a swing shaft 21A and a pair of coupling parts 21B. One end of the swing shaft 21A is connected to the mirror portion 20, and the other end thereof is connected to the coupling part 21B. One end of the coupling part 21B is connected to the outer end portion E1 on the first axis a₁ of the swing shaft 21A, and the other end thereof is connected to the movable frame 22. In the present embodiment, the coupling part 21B does not have a folded structure. That is, the coupling part 21B extends from the outer end portion E1 on the first axis a₁ of the swing shaft 21A in a direction toward the mirror portion 20 and is connected to the movable frame 22 in a region adjacent to the mirror portion 20.

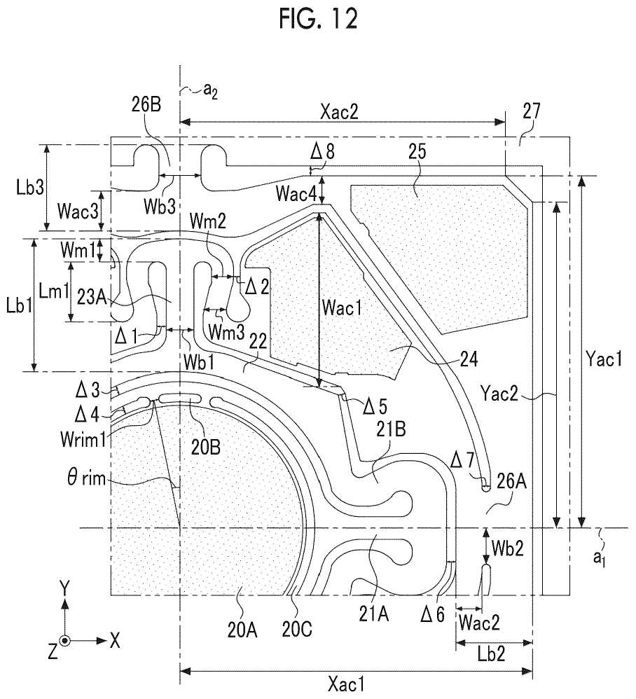

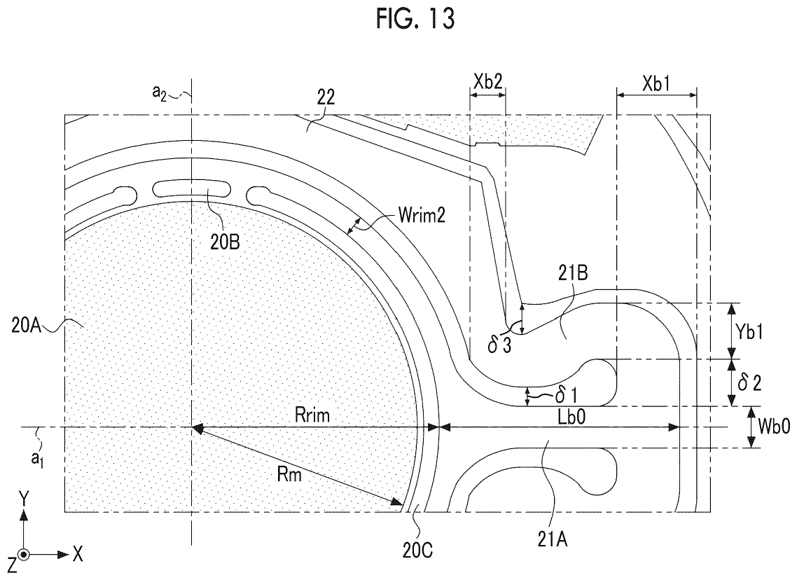

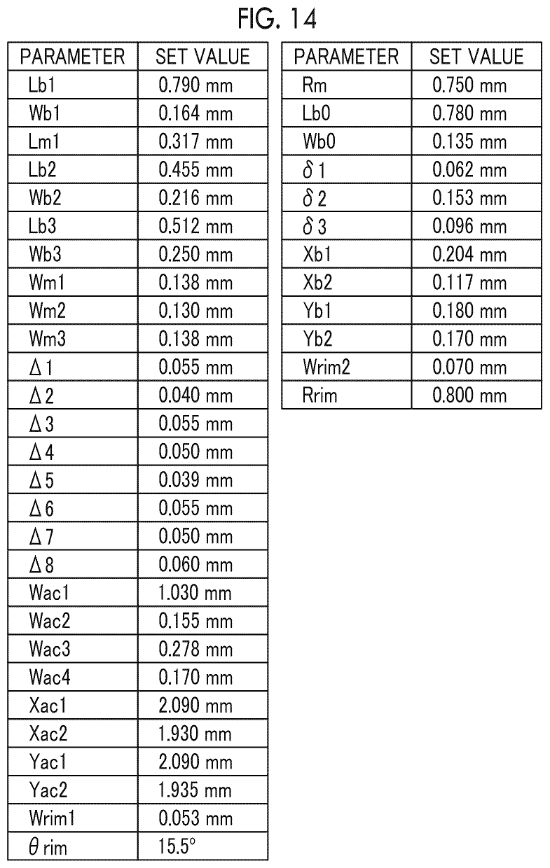

The present applicant also performed the same experiments and simulations as described above on the MMD 2A according to the second embodiment. FIGS. 12 and 13 show parameters relating to the width, length, and the like of the components of the sample used in the experiment. FIG. 14 is a diagram showing specific set values of the parameters.

As a result of the experiment, the required driving voltage at θ=11.25° was 3.7 V. In addition, as a result of the resonance mode analysis simulation, the calculated value of the Mises stress applied to the second support portion 23 when θ=11.25° was 1.77 GPa.

### Third Embodiment

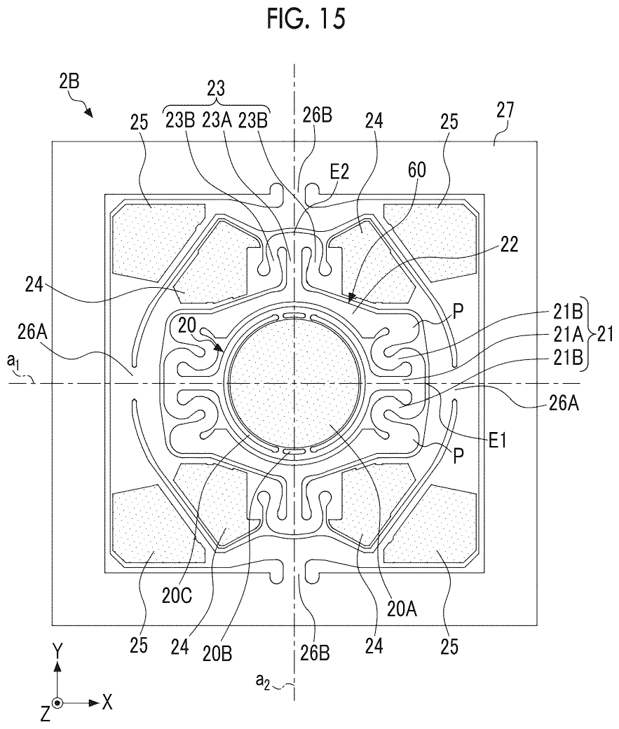

Next, a third embodiment will be described. FIG. 15 is a plan view of the MMD 2B according to the third embodiment as viewed from the light incident side. The MMD 2B is different from the MMD 2 according to the first embodiment only in the configuration of the first support portion 21.

In the present embodiment, the first support portion 21 is configured with a swing shaft 21A and a pair of coupling parts 21B. One end of the swing shaft 21A is connected to the mirror portion 20, and the other end thereof is connected to the coupling part 21B. One end of the coupling part 21B is connected to the outer end portion E1 on the first axis a₁ of the swing shaft 21A, and the other end thereof is connected to the movable frame 22. In the present embodiment, the coupling part 21B has a folded structure.

Specifically, as in the first embodiment, the coupling part 21B extends in a direction from the outer end portion E1 of the swing shaft 21A on the first axis a₁ toward the mirror portion 20, is bent in the outer circumferential direction in a region adjacent to the mirror portion 20, and is bent again in a region adjacent to the first actuator 24 to be connected to the movable frame 22. The coupling part 21B of the present embodiment is different from the coupling part 21B of the first embodiment in that the coupling part 21B protrudes from a portion connected to the movable frame 22 to the outer end portion E1 of the swing shaft 21A on the first axis a₁ in the direction of the first axis a₁. Reference numeral P indicates a region where the coupling part 21B protrudes in the direction of the first axis a₁.

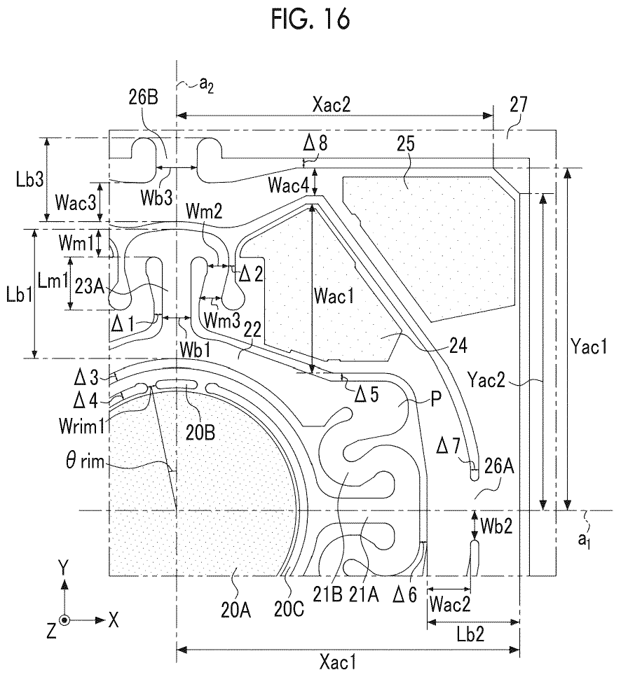

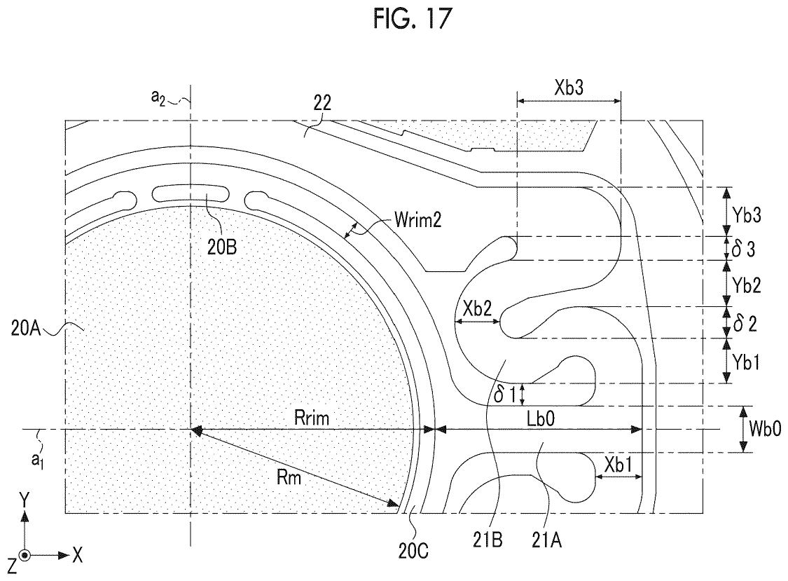

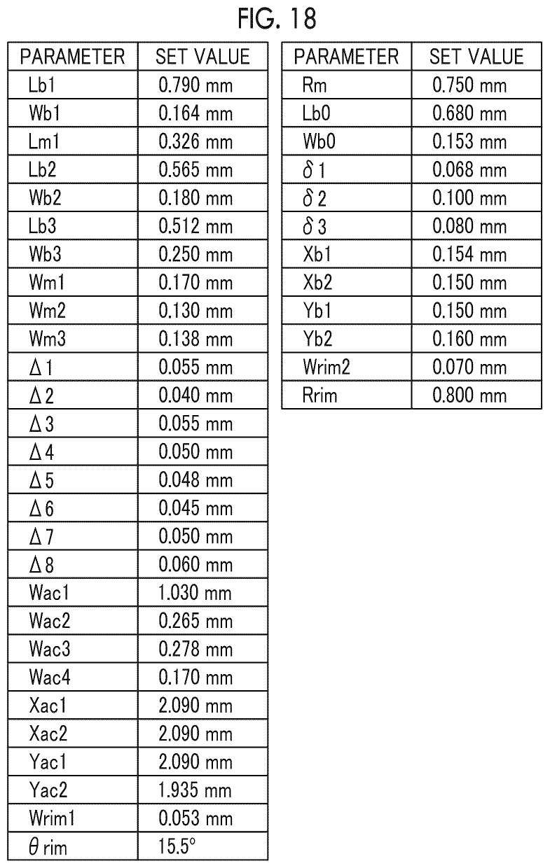

The present applicant also performed the same experiments and simulations as described above on the MMD 2B according to the third embodiment. FIGS. 16 and 17 show parameters relating to the width, length, and the like of the components of the sample used in the experiment. FIG. 18 is a diagram showing specific set values of the parameters.

As a result of the experiment, the required driving voltage at θ=11.25° was 3.5 V. In addition, as a result of the resonance mode analysis simulation, the calculated value of the Mises stress applied to the second support portion 23 when θ=11.25° was 1.77 GPa.

### Fourth Embodiment

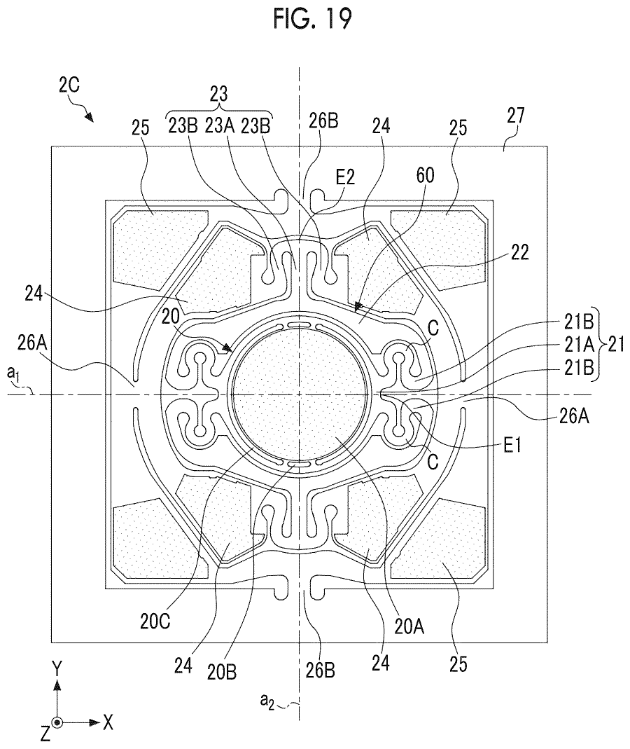

Next, a fourth embodiment will be described. FIG. 19 is a plan view of the MMD 2C according to the fourth embodiment as viewed from the light incident side. The MMD 2C is different from the MMD 2 according to the first embodiment only in the configuration of the first support portion 21.

In the present embodiment, the first support portion 21 is configured with a swing shaft 21A and a pair of coupling parts 21B. One end of the swing shaft 21A is connected to the mirror portion 20, and the other end thereof is connected to the coupling part 21B. One end of the coupling part 21B is connected to the outer end portion E1 on the first axis a₁ of the swing shaft 21A, and the other end thereof is connected to the movable frame 22. In the present embodiment, the coupling part 21B has a folded structure.

Specifically, as in the first embodiment, the coupling part 21B is bent in an outer direction (that is, the second axis a₂ direction) from the outer end portion E1 of the swing shaft 21A on the first axis a₁ and forms an annular region C in a region adjacent to the movable frame 22. In addition, the coupling part 21B extends from the annular region C along the first axis a₁ and extends along the driving part in a region adjacent to the driving part to be connected to the movable frame 22.

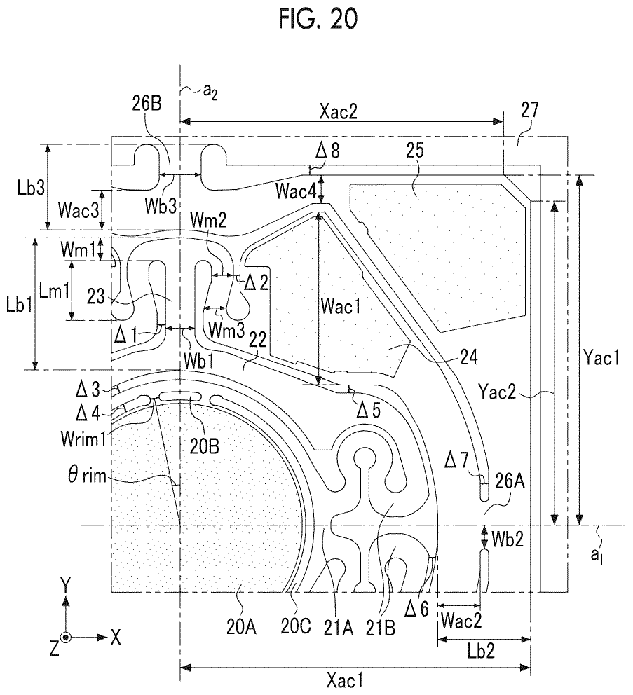

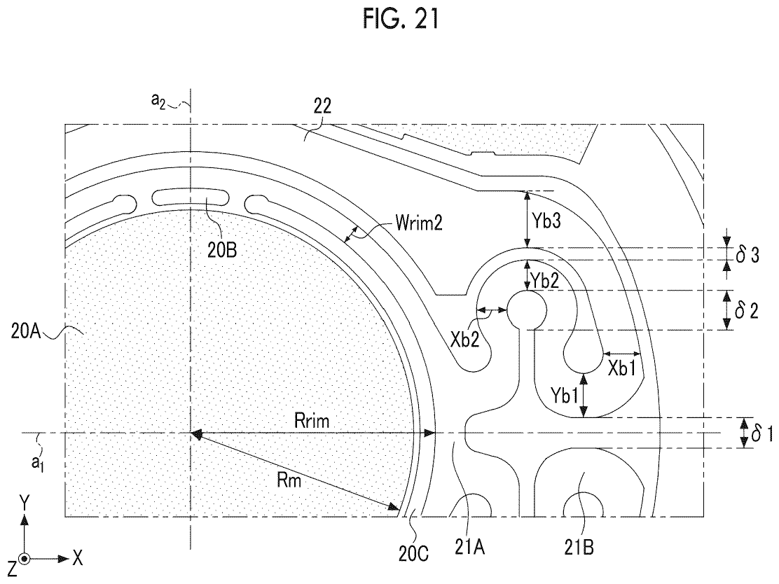

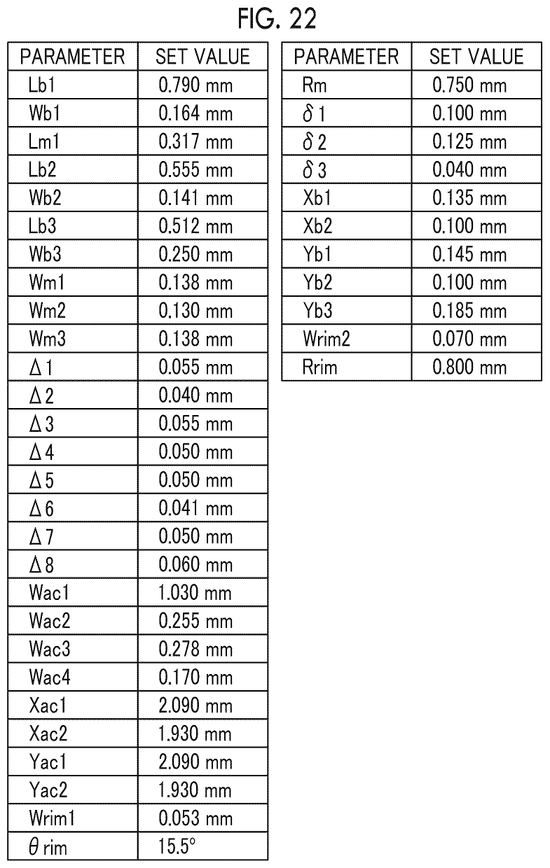

The present applicant also performed the same experiments and simulations as described above on the MMD 2C according to the fourth embodiment. FIGS. 20 and 21 show parameters relating to the width, length, and the like of the components of the sample used in the experiment. FIG. 22 is a diagram showing specific set values of the parameters.

As a result of the experiment, the required driving voltage at θ=11.25° was 3.8 V. In addition, as a result of the resonance mode analysis simulation, the calculated value of the Mises stress applied to the second support portion 23 when θ=11.25° was 1.79 GPa.

### Fifth Embodiment

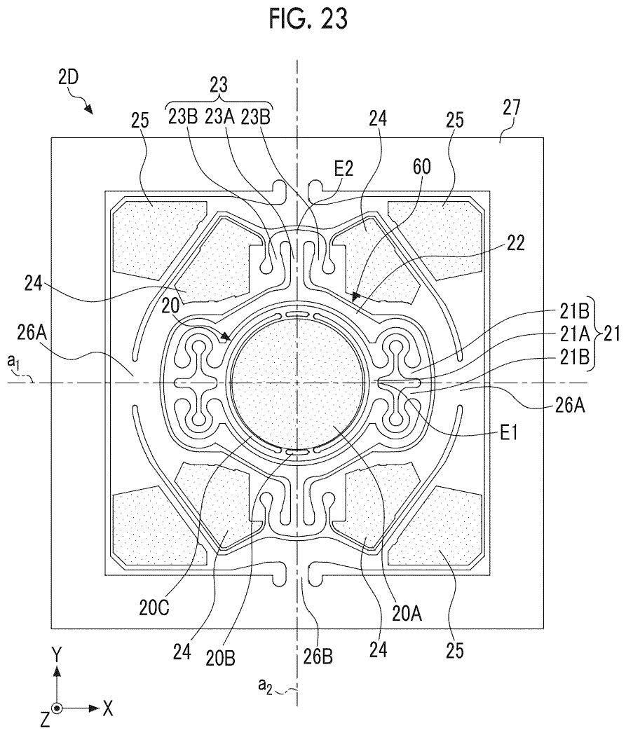

Next, a fifth embodiment will be described. FIG. 23 is a plan view of the MMD 2D according to the fifth embodiment as viewed from the light incident side. The MMD 2D is different from the MMD 2 according to the first embodiment only in the configuration of the first support portion 21.

In the present embodiment, the first support portion 21 is configured with a swing shaft 21A and a pair of coupling parts 21B. One end of the swing shaft 21A is connected to the mirror portion 20, and the other end thereof is connected to the coupling part 21B. One end of the coupling part 21B is connected to the outer end portion E1 on the first axis a₁ of the swing shaft 21A, and the other end thereof is connected to the movable frame 22. In the present embodiment, the coupling part 21B has a folded structure.

In the present embodiment, the first support portion 21 is connected to the pair of coupling parts 21B in a region adjacent to the driving part in addition to the configuration of the fourth embodiment. The first support portion 21 of the present embodiment has the same configuration as the first support portion 21 of the fourth embodiment except that the pair of coupling parts 21B are connected to the first support portion 21.

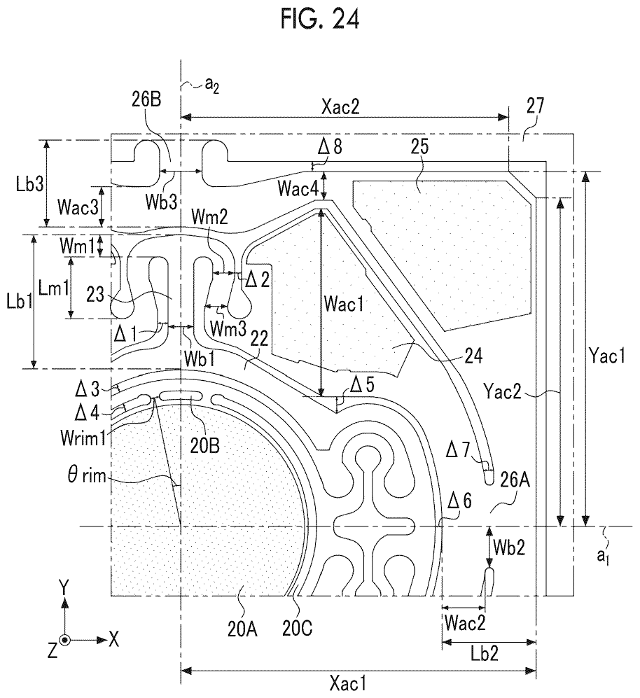

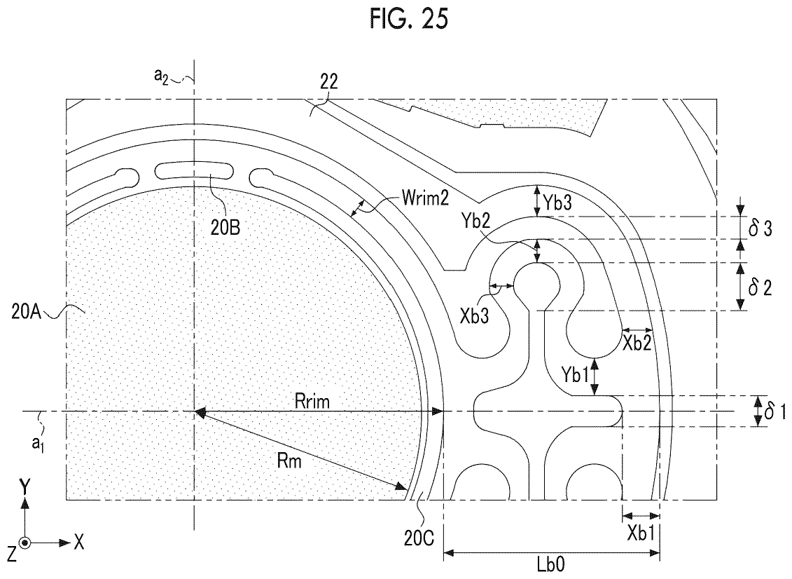

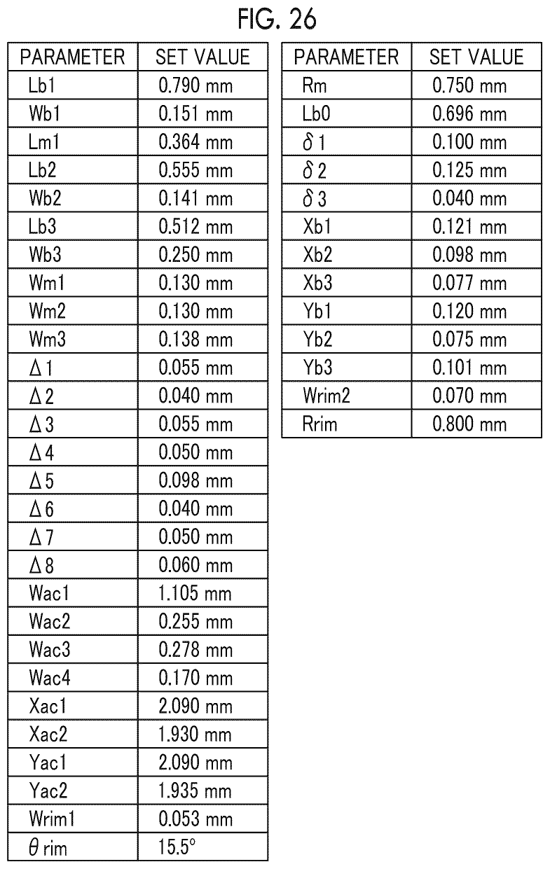

The present applicant also performed the same experiments and simulations as described above on the MMD 2D according to the fifth embodiment. FIGS. 24 and 25 show parameters relating to the width, length, and the like of the components of the sample used in the experiment. FIG. 26 is a diagram showing specific set values of the parameters.

As a result of the experiment, the required driving voltage at θ=11.25° was 3.8 V. In addition, as a result of the resonance mode analysis simulation, the calculated value of the Mises stress applied to the second support portion 23 when θ=11.25° was 1.80 GPa.

### First Comparative Example

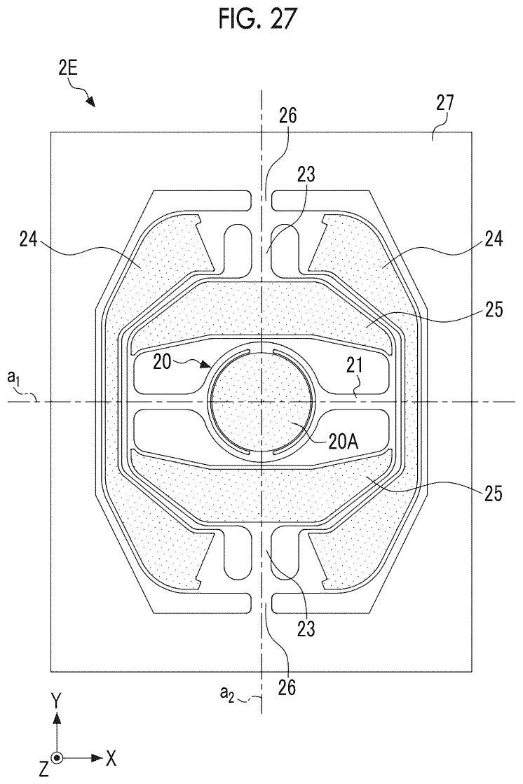

Next, the first comparative example will be described. FIG. 27 is a plan view of the MMD 2E according to the first comparative example as viewed from a light incident side. The MMD 2E is different from the MMD 2 according to the first embodiment in that the first support portion 21 and the second support portion 23 do not have the folded structure and the first support portion 21 and the second support portion 23 are directly connected to the driving part. In addition, in the first comparative example, the first support portion 21 is connected to the fixed frame 27 through the connecting portion 26 on the second axis a₂. Further, in the first comparative example, the movable frame 22 is not provided, and the first actuator 24 is disposed to surround the second actuator 25.

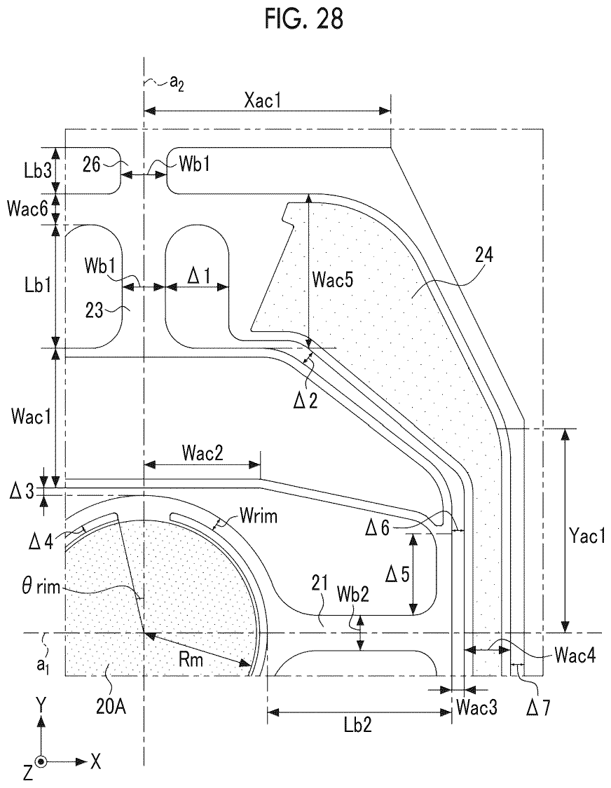

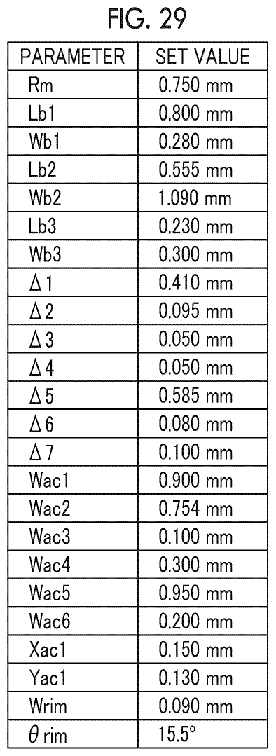

The present applicant also performed the same experiments and simulations as described above on the MMD 2E according to the first comparative example. FIG. 28 shows parameters relating to the width, length, and the like of the components of the sample used in the experiment. FIG. 29 is a diagram showing specific set values of the parameters.

In addition, the diameter of the mirror portion 20 was set to 1.5 mm, the thickness of the SOI substrate 30 was set to 430 μm, and the thickness of the second silicon active layer 33 was set to 100 μm. In addition, the lengths of the fixed frame 27 in the X direction and the Y direction were set to 6.2 mm and 8.6 mm, respectively.

As a result of the experiment, the required driving voltage at θ=11.25° was 3.2 V. In addition, as a result of the resonance mode analysis simulation, the calculated value of the Mises stress applied to the second support portion 23 when θ=11.25° was 2.155 GPa.

### Second Comparative Example

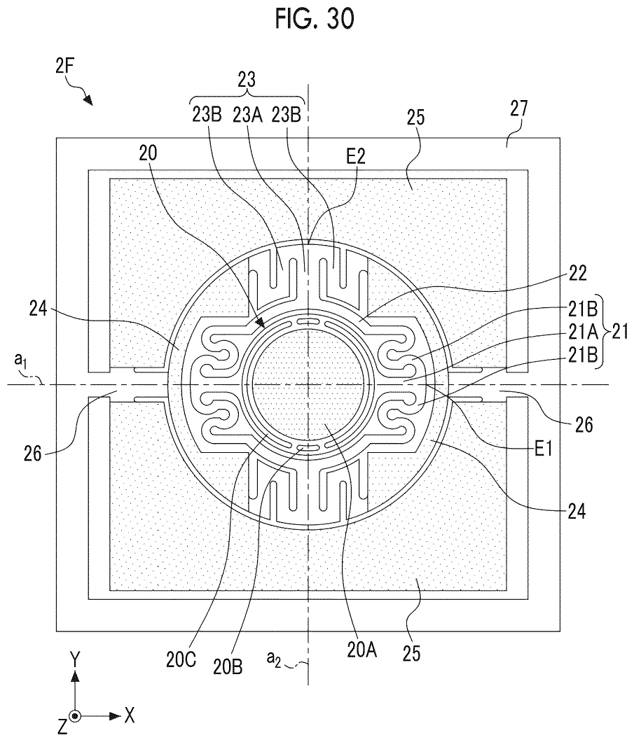

Next, a second comparative example will be described. FIG. 30 is a plan view of the MMD 2F according to the second comparative example as viewed from the light incident side. In the MMD 2F, the first support portion 21 and the second support portion 23 have the folded structure, but the structure of the second support portion 23 is different from that of the MMD 2 according to the first embodiment. In the second comparative example, the coupling part 23B of the second support portion 23 extends in a direction from the outer end portion E2 of the swing shaft 23A on the second axis a₂ toward the mirror portion 20, and is bent in a region adjacent to the movable frame 22 and extends in a direction toward the second actuator 25. The coupling part 23B is connected to the first actuator 24 in a region adjacent to the second actuator 25. In addition, in the second comparative example, the first actuator 24 is connected to the second actuator 25 and the fixed frame 27 via the connecting portion 26 on the first axis a₁.

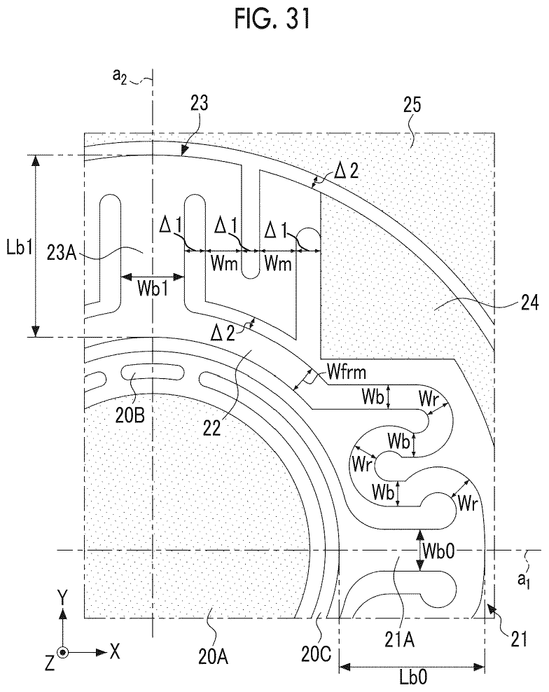

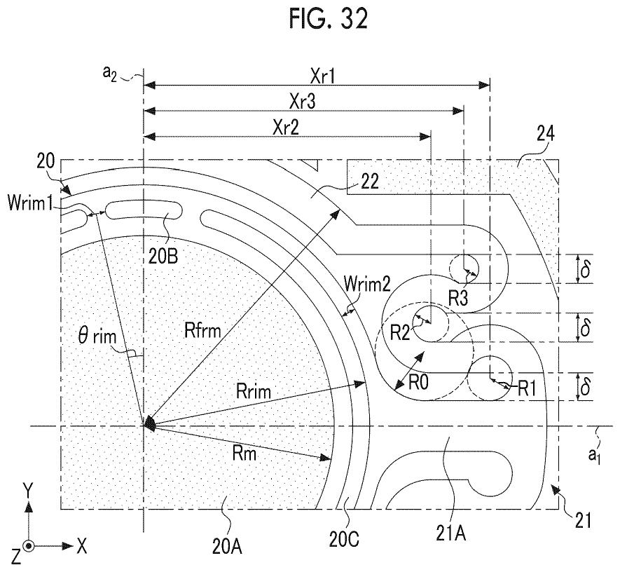

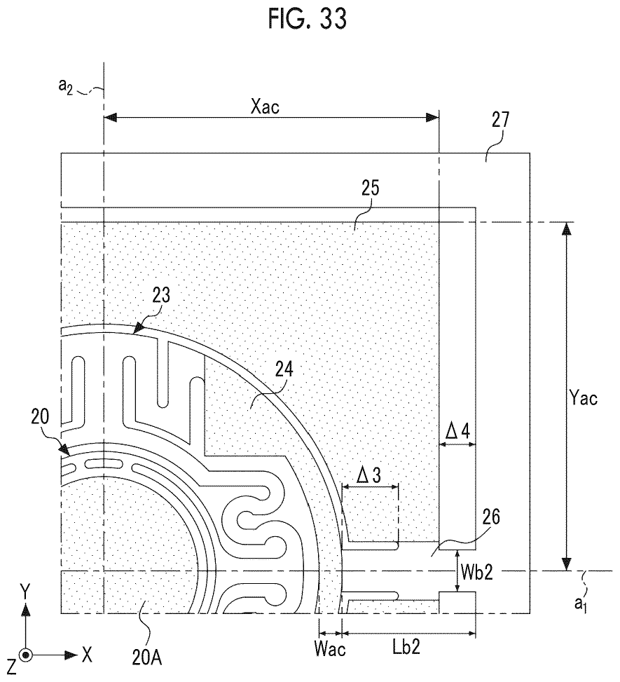

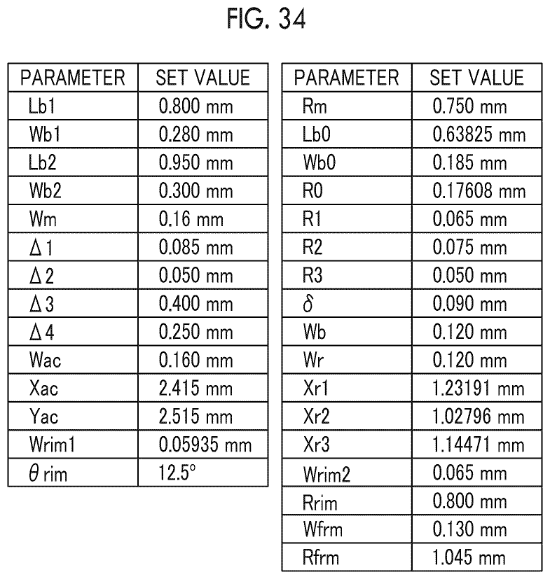

The present applicant also performed the same experiments and simulations as described above on the MMD 2F according to the second comparative example. FIGS. 31 to 33 show parameters relating to the width, length, and the like of the components of the sample used in the experiment. FIG. 34 is a diagram showing specific set values of the parameters.

In addition, the diameter of the mirror portion 20 was set to 1.5 mm, the thickness of the SOI substrate 30 was set to 350 μm, and the thickness of the second silicon active layer 33 was set to 60 μm. The length of one side of the fixed frame 27 was 6.1 mm.

In the configuration of the MMD 2F according to the second comparative example, since the mirror portion 20 cannot be resonantly driven in the anti-phase rotation mode around the second axis a₂, the mirror portion 20 is resonantly driven in the in-phase rotation mode around the second axis a₂.

As a result of the experiment, the required driving voltage at θ=11.25° was 18 V. In addition, as a result of the resonance mode analysis simulation, the calculated value of the Mises stress applied to the second support portion 23 when θ=11.25° was 1.225 GPa.

### CONCLUSION

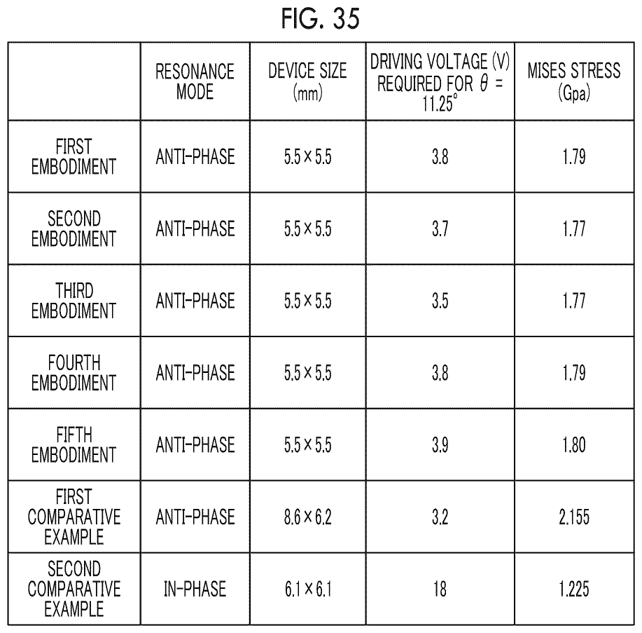

FIG. 35 shows the results of experiments and simulations according to the above-described embodiments and comparative examples. In the use application of the laser display, θ=11.25° (that is, an optical total angle of) 45° is one indicator that enables the optical system to be reduced to a level at which the MMD can be mounted on AR glasses. In a case where the MMD is driven for a long time with AR glasses or the like, it is desirable that the required driving voltage at θ=11.25° is less than 10 V in consideration of power consumption. In addition, in order to prevent the structural destruction of the swing shaft 23A, it is desirable that the Mises stress applied to the second support portion 23 at θ=11.25° is less than 2 GPa.

In the first comparative example, since the second support portion 23 does not have the folded structure and is directly connected to the driving part, the second support portion 23 is greatly twisted in a case where the mirror portion 20 and the first actuator 24 swing in anti-phases, and a large stress is generated. In the first comparative example, since the Mises stress applied to the second support portion 23 is 2 GPa or more at θ=11.25°, there is a high risk of structural destruction of the second support portion 23.

In the second comparative example, the mirror portion 20 and the first actuator 24 swing in the in-phase instead of in anti-phases. In this case, since the internal energy loss of the second support portion 23 in the Si structure during the resonance is large, the Q value is not improved even in a vacuum, and the driving voltage required for θ=11.25° is 10 V or more. In consideration of the power consumption, it is preferable to suppress the driving voltage to less than 10 V, but in a case where the driving voltage is less than 10 V, a sufficiently large deflection angle cannot be realized in the second comparative example.

As described above, in the first comparative example and the second comparative example, a large deflection angle cannot be realized even though the device size is large and the area of the driving part is large. On the other hand, in each of the above-described embodiments, since the driving voltage required for θ=11.25° is less than 10 V and the Mises stress applied to the second support portion 23 at θ=11.25° is less than 2 GPa, a large deflection angle can be realized without increasing the area of the driving part.

In the above embodiment, the hardware configuration of the driving controller 4 can be variously modified. The processing unit of the driving controller 4 may be composed of one processor or may be composed of a combination of two or more processors of the same type or different types. The processor includes, for example, a CPU, a programmable logic device (PLD), or a dedicated electric circuit. As is well known, the CPU is a general-purpose processor that executes software (program) to function as various processing units. The PLD is a processor such as a field programmable gate array (FPGA) whose circuit configuration can be changed after manufacture. The dedicated electric circuit is a processor that has a dedicated circuit configuration designed to perform a specific process, such as an application specific integrated circuit (ASIC).

All of the publications, the patent applications, and the technical standards described in the specification are incorporated by reference herein to the same extent as each individual document, each patent application, and each technical standard are specifically and individually stated to be incorporated by reference.

What is claimed is:

1. A micromirror device comprising:
a mirror portion that has a reflecting surface for reflecting incident light;
a pair of first support portions that are connected to the mirror portion on a first axis located in a plane including the reflecting surface in a stationary state of the mirror portion and that support the mirror portion to be swingable around the first axis;
a pair of movable frames that are connected to the first support portions and that face each other across the first axis;
a pair of second support portions that are connected to the movable frames on a second axis provided in the plane and perpendicular to the first axis and that support the mirror portion, the first support portions, and the movable frames to be swingable around the second axis;
a driving part that is connected to the second support portions and that is disposed to surround the movable frames;
a fixed frame that is disposed to surround the driving part; and
a pair of connecting portions that connect the driving part and the fixed frame,
wherein the first support portion has a shape that is line-symmetrical about the first axis,
the second support portion has a shape that is line-symmetrical about the second axis and includes a second swing shaft disposed on the second axis and a pair of second coupling parts disposed at positions facing each other across the second axis,
one end of the second swing shaft is connected to the movable frame and the other end of the second swing shaft is connected to the second coupling part,
the second coupling part extends in a direction from an outer end portion of the second swing shaft on the second axis toward the mirror portion and is connected to the driving part in a region adjacent to the movable frame, and
the connecting portion has a shape that is line-symmetrical about the second axis and supports the driving part to be swingable around the second axis.

2. The micromirror device according to claim 1,
wherein the driving part includes
a pair of first actuators that are connected to the second support portion, that face each other across the second axis, and that each include a piezoelectric element, and
a pair of second actuators that are disposed to surround the first actuators, that face each other across the first shaft, and that each include a piezoelectric element.

3. The micromirror device according to claim 2,
wherein the connecting portions are disposed on the second axis.

4. The micromirror device according to claim 1,
wherein the first support portion includes
a first swing shaft having a shape that is line-symmetrical about the first axis, and disposed on the first axis, and
a pair of first coupling parts disposed at positions facing each other across the first axis.

5. The micromirror device according to claim 4,
wherein one end of the first swing shaft is connected to the mirror portion and the other end of the first swing shaft is connected to the first coupling part, and
the first coupling part extends in a direction from an outer end portion of the first swing shaft on the first axis toward the mirror portion, is bent in an outer circumferential direction in a region adjacent to the mirror portion, and is bent again in a region adjacent to the driving part to be connected to the movable frame.

6. The micromirror device according to claim 4,
wherein one end of the first swing shaft is connected to the mirror portion and the other end of the first swing shaft is connected to the first coupling part, and
the first coupling part extends in a direction from an outer end portion of the first swing shaft on the first axis toward the mirror portion and is connected to the movable frame in a region adjacent to the mirror portion.

7. The micromirror device according to claim 5,
wherein the first coupling part protrudes from a portion connected to the movable frame to an outer end portion of the first swing shaft on the first axis in a direction of the first axis.

8. The micromirror device according to claim 4,
wherein the first coupling part is bent in an outward direction from an outer end portion of the first swing shaft on the first axis, forms an annular region in a region adjacent to the movable frame, further extends from the annular region along the first axis, and extends along the driving part in a region adjacent to the driving part to be connected to the movable frame.

9. The micromirror device according to claim 8,
wherein the pair of first coupling parts are connected in a region adjacent to the driving part.

10. An optical scanning device comprising:
the micromirror device according to claim 1; and
a processor that drives the driving part,
wherein the processor applies a drive signal to the driving part to cause the mirror portion to swing around each of the first axis and the second axis.
